(19) United States
(12) Patent Application Publication
(10) Pub. No.: US 2024/0200190 A1
(43) Pub. Date: Jun. 20, 2024

(54) SHOWER HEAD AND SUBSTRATE PROCESSING APPARATUS INCLUDING THE SHOWER HEAD

(71) Applicant: SAMSUNG ELECTRONICS CO., LTD., Suwon-si (KR)

(72) Inventors: Dae Wee Kong, Suwon-si (KR); Taewon Lee, Suwon-si (KR); Sangho Roh, Suwon-si (KR); SongYi Baek, Suwon-si (KR)

(73) Assignee: SAMSUNG ELECTRONICS CO., LTD., Suwon-si (KR)

(21) Appl. No.: 18/381,006

(22) Filed: Oct. 17, 2023

(30) Foreign Application Priority Data
Dec. 14, 2022 (KR) 10-2022-0174561
Apr. 3, 2023 (KR) 10-2023-0043713

(51) Int. Cl. C23C 16/455; H01J 37/32

(52) U.S. Cl. CPC C23C 16/45565; H01J 37/3244; H01J 37/32091; H01J 2237/3321

(57) ABSTRACT

A shower head may include a lower shower head part including a lower plate. The lower plate includes a lower plate, the lower plate includes a plurality of gas holes, the plurality of gas holes includes: a vertical hole vertically penetrating the lower plate in a first direction; and an inclined hole penetrating the lower plate in a second direction, which is inclined at an acute angle with respect to the first direction of the vertical hole, the vertical hole has a first diameter and the inclined hole has a second diameter which is different than the first diameter.

### CROSS-REFERENCE TO RELATED APPLICATIONS

This application claims priority under 35 U.S.C. § 119 to Korean Patent Application No. 10-2022-0174561, filed on Dec. 14, 2022, and Korean Patent Application No. 10-2023-0043713, filed on Apr. 3, 2023, in the Korean Intellectual Property Office, the entire contents of which are incorporated by reference herein.

### BACKGROUND

The present disclosure relates to a shower head and a substrate processing apparatus therewith, and in particular, to a shower head which can uniformly supply a process gas and a substrate processing apparatus including the shower head.

A semiconductor device may be fabricated through various processes, for example, a photolithography process, an etching process, and a deposition process on a wafer. Various fluidic materials are used in these processes. For example, the etching process and/or the deposition process may be performed using process gas and/or plasma. A shower head may be used to uniformly supply the process gas on the wafer.

### SUMMARY

Example embodiments provide a shower head using a thick supporting pillar and a substrate processing apparatus therewith.

Example embodiments provide a shower head, which can uniformly supply a process gas, and a substrate processing apparatus including the shower head.

Further, example embodiments provide a shower head with an increased life span and a substrate processing apparatus including the shower head.

According to an aspect of an example embodiment, a shower head includes: a lower shower head part, wherein the lower shower head part includes a lower plate, the lower plate includes a plurality of gas holes, the plurality of gas holes includes: a vertical hole vertically penetrating the lower plate in a first direction; and an inclined hole penetrating the lower plate in a second direction, which is inclined at an acute angle with respect to the first direction of the vertical hole, the vertical hole has a first diameter and the inclined hole has a second diameter which is different than the first diameter.

According to an aspect of an example embodiment, a shower head includes: a lower shower head part; and an upper shower head part on the lower shower head part, wherein the lower shower head part includes: a lower plate that includes a plurality of gas holes; and at least one supporting pillar extended from a top surface of the lower plate and coupled to the upper shower head part, the plurality of gas holes includes: a vertical hole penetrating the lower plate in a first direction; and an inclined hole penetrating the lower plate and spaced apart from the vertical hole, an upper end of the inclined hole, which meets the top surface of the lower plate, is beside the at least one supporting pillar, and a lower end of the inclined hole, which meets a bottom surface of the lower plate, is below the at least one supporting pillar.

According to an aspect of an example embodiment, a substrate processing apparatus including: a shower head, wherein the shower head includes a lower shower head part, the lower shower head part includes: a lower plate that includes a plurality of gas holes; and a supporting pillar extended upward from a top surface of the lower plate, the lower plate includes: at least one supporting portion which at least partially overlaps the supporting pillar, in a plan view; and a distribution portion which does not overlap the supporting pillar and is beside the at least one supporting portion, in a plan view, the plurality of gas holes includes: a first gas holes in the distribution portion and arranged in a first pattern on a top surface of the distribution portion, a second gas holes in the distribution portion and arranged in the first pattern on a bottom surface of the distribution portion, a third gas holes in the at least one supporting portion and arranged in a second pattern on a top surface of the at least one supporting portion, the second pattern being different from the first pattern, and a fourth gas holes in the at least one supporting portion and arranged in the first pattern on a bottom surface of the at least one supporting portion.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a sectional view illustrating a substrate processing apparatus according to an embodiment of the disclosure;

FIG. 2 is an enlarged sectional view illustrating a portion ‘X’ of FIG. 1;

FIG. 3 is a sectional view illustrating a shower head according to an embodiment of the disclosure;

FIG. 4 is an exploded sectional view illustrating a shower head according to an embodiment of the disclosure;

FIG. 5 is a plan view illustrating a lower shower head part of the shower head, according to an embodiment of the disclosure;

FIG. 6 is an enlarged sectional view illustrating a portion ‘Y’ of FIG. 3;

FIG. 7 is an enlarged plan view illustrating a portion ‘Z’ of FIG. 5;

FIG. 8 is a plan view illustrating a portion of the lower shower head part according to an embodiment of the disclosure;

FIG. 9 is a bottom plan view illustrating a portion of the lower shower head part of the shower head according to an embodiment of the disclosure;

FIG. 10 is a flow chart illustrating a substrate processing method according to an embodiment of the disclosure;

FIGS. 11 to 14 are diagrams illustrating a substrate processing method according to the flow chart of FIG. 10;

FIG. 15 is a sectional view illustrating a portion of a shower head according to an embodiment of the disclosure;

FIG. 16 is a sectional view illustrating a portion of a shower head according to an embodiment of the disclosure; and

FIG. 17 is a sectional view illustrating a portion of a shower head according to an embodiment of the disclosure.

### DETAILED DESCRIPTION

Example embodiments of the disclosure will now be described more fully with reference to the accompanying drawings. Like reference numerals in the drawings denote like elements, and thus, their description will be omitted.

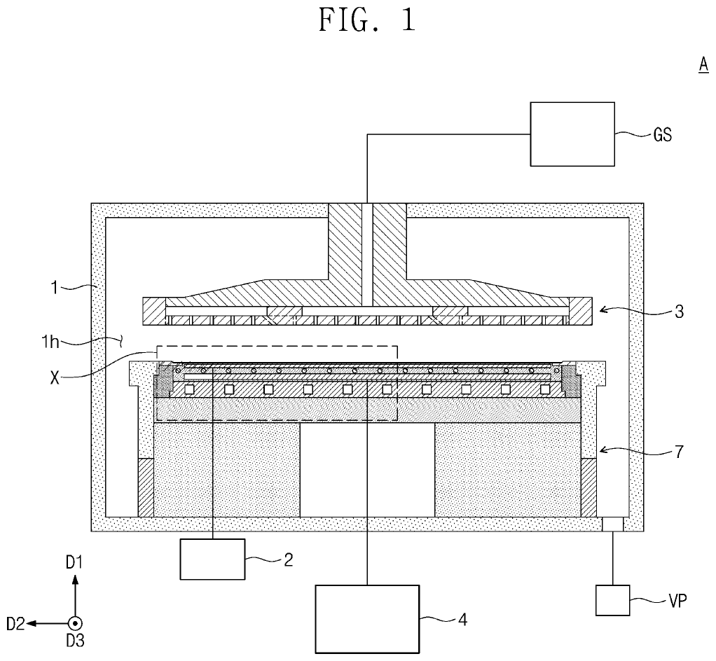

FIG. 1 is a sectional view illustrating a substrate processing apparatus according to an embodiment of the disclosure.

In the disclosure, the reference numbers D1, D2, and D3 will be used to denote a first direction, a second direction, and a third direction, respectively, which are not parallel to each other. The first direction D1 may be referred to as a vertical direction. Each of the second and third directions D2 and D3 may be referred to as a horizontal direction.

Referring to FIG. 1, a substrate processing apparatus A may be configured to treat a substrate using a fluidic material. For example, the substrate processing apparatus A may be configured to perform a process of forming a thin film on a substrate. More specifically, the substrate processing apparatus A may be configured to perform a chemical vapor deposition (CVD) process on a substrate. However, the disclosure is not limited to this example, and the substrate processing apparatus A may be configured to perform other deposition process or an etching process on the substrate. In the present specification, the term ‘substrate’ may mean a silicon wafer, but the disclosure is not limited to this example. The substrate processing apparatus A may be configured to treat the substrate using plasma. For this, the substrate processing apparatus A may be configured to generate plasma in various manners. For example, the substrate processing apparatus A may be a capacitively coupled plasmas (CCP) apparatus. The substrate processing apparatus A may include a process chamber 1, a stage 7, a shower head 3, a DC power generating unit 2, an RF power generating unit 4, a vacuum pump VP, and a gas supplying device GS.

The process chamber 1 may be provided to define a process space 1h. In the process space 1h, a fabrication process may be performed on the substrate. The process space 1h may be isolated from an external space. During the fabrication process on the substrate, the process space 1h may be in a substantially vacuum state. The process chamber 1 may have a cylindrical shape, but the disclosure is not limited to this example.

The stage 7 may be placed in the process chamber 1. That is, the stage 7 may be placed in the process space 1h. The stage 7 may be configured to support and/or hold the substrate. The fabrication process may be performed on the substrate, which is loaded on the stage 7. The stage 7 will be described in more detail below.

The shower head 3 may be placed in the process chamber 1. That is, the shower head 3 may be placed in the process space 1h. The shower head 3 may be spaced apart from the stage 7 in an upward direction. Gas, which is supplied from the gas supplying device GS, may be uniformly sprayed into the process space 1h through the shower head 3. The shower head 3 will be described in more detail below.

The DC power generating unit 2 may be configured to apply a DC power to the stage 7. The DC power from the DC power generating unit 2 may be used to fasten the substrate to a specific position on the stage 7.

The RF power generating unit 4 may be configured to supply an RF power to the stage 7. The RF power may be used to control plasma in the process space 1h. This will be described in more detail below.

The vacuum pump VP may be connected to the process space 1h. A vacuum pressure may be applied to the process space 1h by the vacuum pump VP, when a process is performed on the substrate.

The gas supplying device GS may be configured to supply gas into the process space 1h. For this, the gas supplying device GS may include a gas tank, a compressor, and a valve. A portion of the gas, which is supplied into the process space 1h by the gas supplying device GS, may be used to form the plasma.

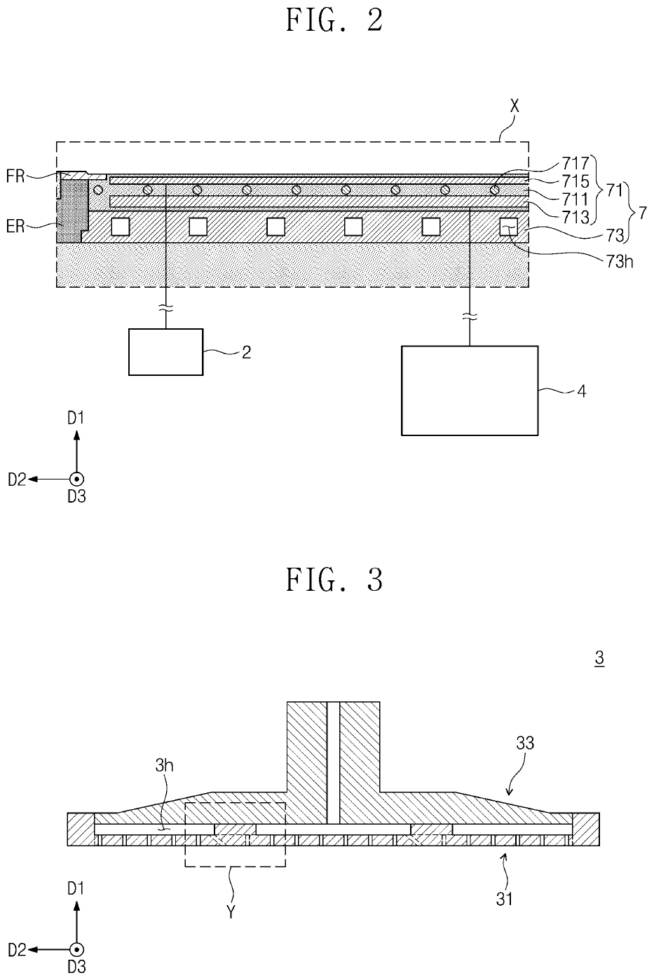

FIG. 2 is an enlarged sectional view illustrating a portion ‘X’ of FIG. 1.

Referring to FIG. 2, the stage 7 may include a chuck 71 and a cooling plate 73.

A substrate may be disposed on the chuck 71. The chuck 71 may be configured to fasten the substrate to a specific position. For this, the chuck 71 may include a chuck body 711, a plasma electrode 713, a chuck electrode 715, and a heater 717.

The chuck body 711 may have a shape of a circular cylinder. The chuck body 711 may be formed of or include a ceramic material, but the disclosure is not limited to this example. A substrate may be disposed on a top surface of the chuck body 711. A focus ring FR and/or an edge ring ER may be provided to enclose the chuck body 711.

The plasma electrode 713 may be placed in the chuck body 711. The plasma electrode 713 may be formed of or include aluminum (Al). The plasma electrode 713 may have a shape of a circular plate, but the disclosure is not limited to this example. An RF power may be applied to the plasma electrode 713. More specifically, the RF power generating unit 4 may apply the RF power to the plasma electrode 713. Plasma in the process space 1h (e.g., see FIG. 1) may be controlled by the RF power applied to the plasma electrode 713.

The chuck electrode 715 may be placed in the chuck body 711. The chuck electrode 715 may be placed above the plasma electrode 713. A DC power may be applied to the chuck electrode 715. More specifically, the DC power generating unit 2 may apply the DC power to the chuck electrode 715. The substrate on the chuck body 711 may be fastened to a specific position by the DC power applied to the chuck electrode 715. The chuck electrode 715 may be formed of or include aluminum (Al), but the disclosure is not limited to this example.

The heater 717 may be placed in the chuck body 711. The heater 717 may be placed between the chuck electrode 715 and the plasma electrode 713. The heater 717 may include a heating line. For example, the heater 717 may include a heating line, which is provided in a concentric manner. The heater 717 may dissipate heat energy toward neighboring elements. Accordingly, the chuck body 711 or the like may be heated.

The cooling plate 73 may be placed below the chuck 71. That is, the chuck 71 may be placed on the cooling plate 73. The cooling plate 73 may be provided to define a cooling hole 73h. Cooling water may flow through the cooling hole 73h. The cooling water in the cooling hole 73h may be used to absorb heat energy from the cooling plate 73.

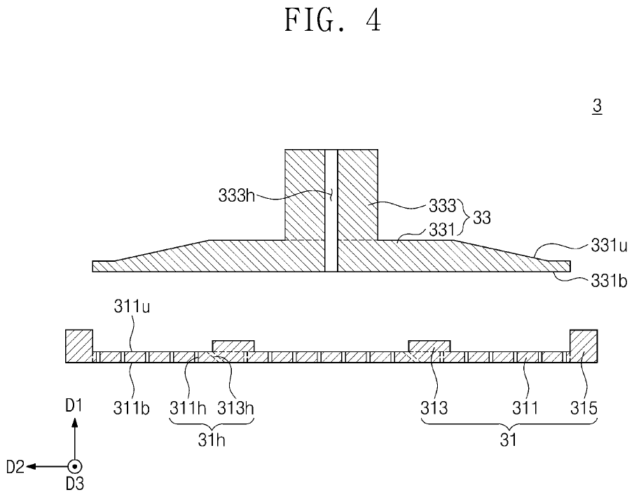

FIG. 3 is a sectional view illustrating a shower head according to an embodiment of the disclosure, and FIG. 4 is an exploded sectional view illustrating a shower head according to an embodiment of the disclosure.

Referring to FIGS. 3 and 4, the shower head 3 may include a lower shower head part 31 and an upper shower head part 33.

The lower shower head part 31 may include a lower plate 311, a supporting pillar 313, and an edge coupling ring 315.

The lower plate 311 may be provided to define gas holes 31h. The lower plate 311 may include gas holes 31h. The gas holes 31h may be provided to penetrate the lower plate 311. The gas holes 31h may connect a top surface 311u of the lower plate 311 to a bottom surface 311b of the lower plate 311. The bottom surface 311b and/or the top surface 311u of the lower plate 311 may have a flat or substantially flat shape. That is, the lower plate 311 may have a constant or substantially constant thickness. However, the disclosure is not limited to this example. In an embodiment, a plurality of gas holes 31h may be provided. The gas holes 31h may be spaced apart from each other in the horizontal direction. For example, the gas holes 31h may include a vertical hole 311h and an inclined hole 313h. In order to reduce complexity in the description, one of the gas holes 31h will be described exemplarily, unless the context clearly indicates otherwise. The gas holes 31h will be described in more detail below. In an embodiment, the lower plate 311 may be formed of or include aluminum (Al), but the disclosure is not limited to this example.

The supporting pillar 313 may be placed on and coupled to the lower plate 311. More specifically, the supporting pillar 313 may be extended from the top surface 311u of the lower plate 311 in an upward direction. The supporting pillar 313 and the lower plate 311 may be provided to form a single object, but the disclosure is not limited to this example. The supporting pillar 313 may be coupled to the upper shower head part 33. For example, an upper end of the supporting pillar 313 may be extended to a level higher than a bottom surface 331b of an upper plate 331, and a portion of the supporting pillar 313 may be inserted into the upper plate 331. The supporting pillar 313 may be fixedly connected to the upper shower head part 33 using, for example, a welding method or the like. In an embodiment, the supporting pillar 313 may be formed of or include aluminum (Al), but the disclosure is not limited to this example. The supporting pillar 313 will be described in more detail below.

The edge coupling ring 315 may be extended upward from an edge portion of the lower plate 311. In an embodiment, the edge coupling ring 315 and the lower plate 311 may be provided to form a single object. The edge coupling ring 315 may be coupled to the upper shower head part 33. More specifically, the edge coupling ring 315 may be coupled to an edge portion of the upper plate 331. The edge coupling ring 315 and the upper plate 331 may be fixedly connected to each other by a welding method or the like. In an embodiment, the edge coupling ring 315 may be formed of or include aluminum (Al), but the disclosure is not limited to this example. The supporting pillar 313 may be placed inside the edge coupling ring 315.

The upper shower head part 33 may be placed on the lower shower head part 31. The upper shower head part 33 may be coupled to the lower shower head part 31. The upper shower head part 33 may include the upper plate 331 and a supporting member 333.

The upper plate 331 may be spaced apart from the lower plate 311 in an upward direction. A distribution space 3h may be provided between the upper plate 331 and the lower plate 311. More specifically, the distribution space 3h may be provided between the bottom surface 331b of the upper plate 331 and the top surface 311u of the lower plate 311. The distribution space 3h may be connected to the gas holes 31h. The bottom surface 331b of the upper plate 331 may be flat, but the disclosure is not limited to this example. A top surface 331u of the upper plate 331 may include a portion, which has an increasing thickness as a distance to a center of the upper plate 331 decreases.

The supporting member 333 may be extended from the upper plate 331 in an upward direction. The supporting member 333 may be provided to define a gas supplying pathway 333h. The gas supplying pathway 333h may be provided to vertically penetrate the supporting member 333. The gas supplying pathway 333h may be connected to the distribution space 3h. The gas supplying pathway 333h may be connected to the gas supplying device GS (e.g., see FIG. 1). The gas, which is supplied from the gas supplying device GS, may be supplied into the distribution space 3h through the gas supplying pathway 333h. The gas, which is supplied into the distribution space 3h, may be supplied into the process space 1h (e.g., FIG. 1) through the gas holes 31h.

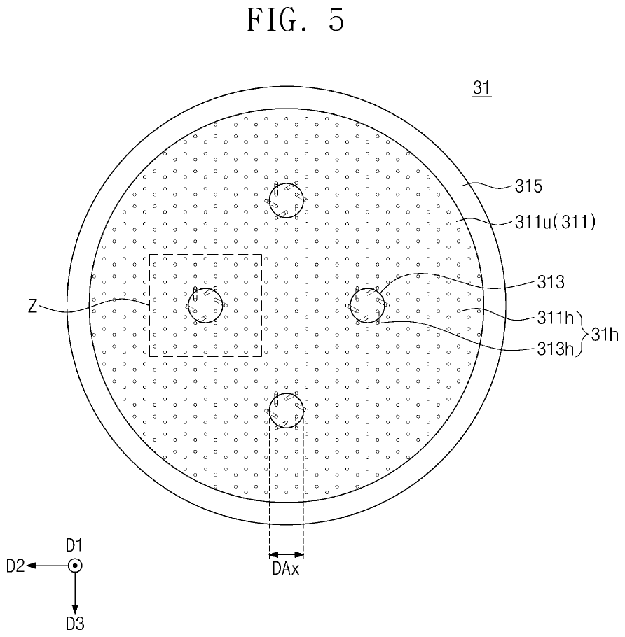

FIG. 5 is a plan view illustrating a lower shower head part according to an embodiment of the disclosure.

Referring to FIG. 5, a plurality of supporting pillars 313 may be provided. For example, four supporting pillars 313 may be provided, as shown in FIG. 5. The supporting pillars 313 may be spaced apart from each other in the horizontal direction. However, in order to reduce complexity in the description, one of the supporting pillars 313 will be described exemplarily, unless the context clearly indicates otherwise. When viewed in a plan view, the supporting pillar 313 may be overlapped with the inclined hole 313h. This will be described in more detail below. For example, a diameter DAx of the supporting pillar 313 may range from about 7 mm to about 13 mm. More specifically, the diameter DAx of the supporting pillar 313 may range from about 8 mm to about 12 mm. However, the disclosure is not limited to this example.

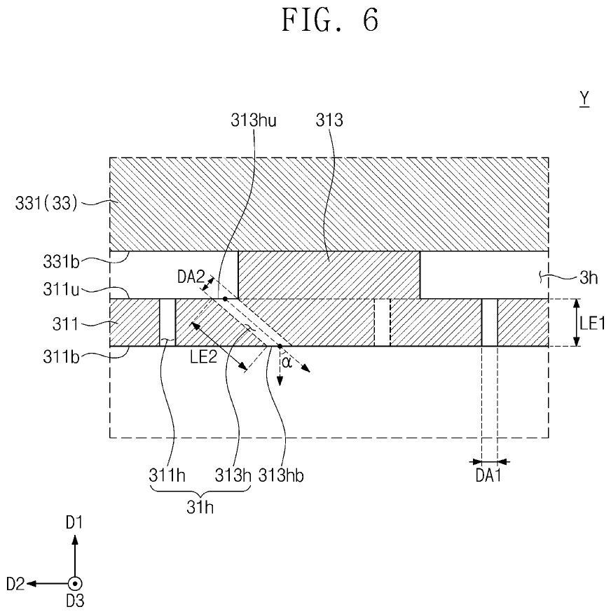

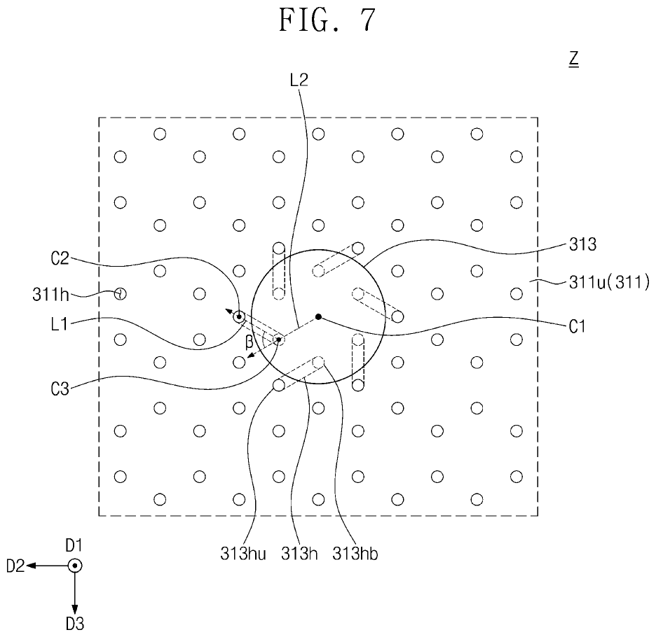

FIG. 6 is an enlarged sectional view illustrating a portion ‘Y’ of FIG. 3, and FIG. 7 is an enlarged plan view illustrating a portion ‘Z’ of FIG. 5.

Referring to FIGS. 6 and 7, the vertical hole 311h may be vertically extended. That is, the vertical hole 311h may penetrate the lower plate 311 in the first direction D1. When viewed in a plan view, the vertical hole 311h may not be overlapped with the supporting pillar 313. A diameter of the vertical hole 311h may be referred to as a first diameter DA1. A length of the vertical hole 311h may be referred to as a first length LE1. The first length LE1 may be substantially equal or similar to a thickness of the lower plate 311. For example, the first length LE1 may be about 10 mm, but the disclosure is not limited to this example. In an embodiment, a plurality of vertical holes 311h may be provided. The vertical holes 311h may be spaced apart from each other in the horizontal direction. However, in order to reduce complexity in the description, one of the vertical holes 311h will be described exemplarily, unless the context clearly indicates otherwise.

The inclined hole 313h may be spaced apart from the vertical hole 311h in the horizontal direction. The inclined hole 313h may be inclined at a first angle α to an extension direction of the vertical hole 311h. The first angle α may be an acute angle. For example, the first angle α may range from about 3 to about 50°, but the disclosure is not limited to this example.

An upper end 313hu of the inclined hole 313h, at which the inclined hole 313h meets the top surface 311u of the lower plate 311, may be placed beside the supporting pillar 313. More specifically, the upper end 313hu of the inclined hole 313h may be spaced apart from the supporting pillar 313 in the horizontal direction. A lower end 313hb of the inclined hole 313h, at which the inclined hole 313h meets the bottom surface 311b of the lower plate 311, may be placed below the supporting pillar 313. More specifically, the lower end 313hb of the inclined hole 313h may be spaced apart from the supporting pillar 313 in the vertical direction. Accordingly, a portion of the inclined hole 313h may be overlapped with the supporting pillar 313, when viewed in a plan view. That is, the lower end 313hb of the inclined hole 313h may be overlapped with the supporting pillar 313, when viewed in a plan view.

A diameter of the inclined hole 313h may be referred to as a second diameter DA2. The second diameter DA2 may be a diameter that is measured in a direction perpendicular to an extension direction of the inclined hole 313h. A length of the inclined hole 313h may be referred to as a second length LE2. The second length LE2 may mean a length in the extension direction of the inclined hole 313h. The second diameter DA2 may be different from the first diameter DA1. For example, the second diameter DA2 may be larger than the first diameter DA1. More specifically, if the gas is a viscous flow, a ratio of the fourth power of the second diameter DA2 to the second length LE2 may be equal to a ratio of the fourth power of the first diameter DA1 to the first length LE1. That is, the following relationship may hold between the first diameter DA1, the second diameter DA2, the first length LE1, and the second length LE2 may be given by:

$$\frac{{( DA 1 )}^{4} =}{LE 1} = \frac{{( DA 2 )}^{4}}{LE 2}$$

For example, if the first length LE1 is 10 mm, the first diameter DA1 is 0.8 mm, and the second length LE2 is 10.8 mm, the second diameter DA2 may be 0.8×(10.8/10)^{1/4} mm. Thus, even when the first length LE1 is different from the second length LE2, it may be possible to remove a difference in conductance between the vertical hole 311h and the inclined hole 313h. Accordingly, an amount of the gas passing through the vertical hole 311h may be controlled to be equal to an amount of the gas passing through the inclined hole 313h. However, the disclosure is not limited to this example, and the first diameter DA1 and the second diameter DA2 may be equal to each other.

When viewed in a plan view, the extension direction of the inclined hole 313h may be inclined at a second angle β to a straight line connecting a center C3 of the lower end 313hb of the inclined hole 313h to a center C1 of the supporting pillar 313. More specifically, a first straight line L1 connecting a center C2 of an upper end 311hu of the inclined hole 313h to the center C3 of a lower end 313hb of the inclined hole 313h may be inclined at the second angle β to a second straight line L2 connecting the center C3 of the lower end 313hb of the inclined hole 313h to the center C1 of the supporting pillar 313. The second angle β may be an acute angle. For example, the second angle β may range from about 3° to about 80. However, the disclosure is not limited to this example.

In an embodiment, a plurality of inclined holes 313h may be provided. For example, six inclined holes 313h may be provided around one supporting pillar 313. The number of the inclined hole 313h may be smaller than the number of the vertical hole 311h. The inclined holes 313h may be spaced apart from each other in the horizontal direction. However, in order to reduce complexity in the description, one of the vertical holes 311h will be described exemplarily, unless the context clearly indicates otherwise.

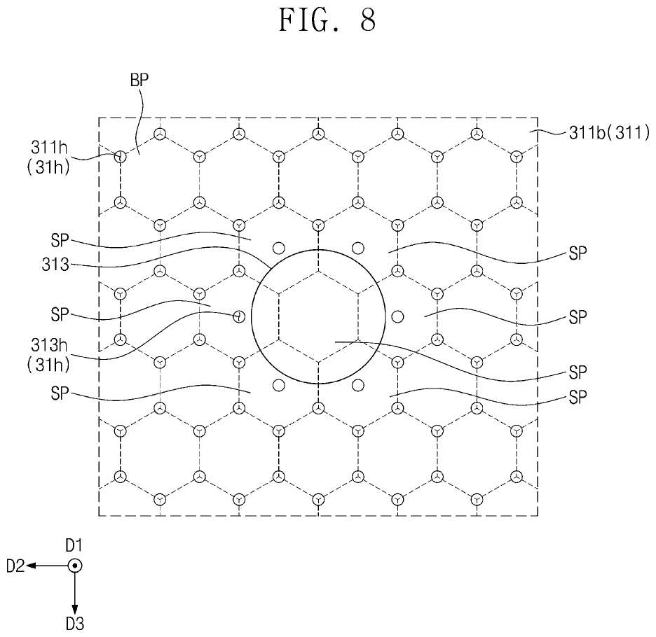

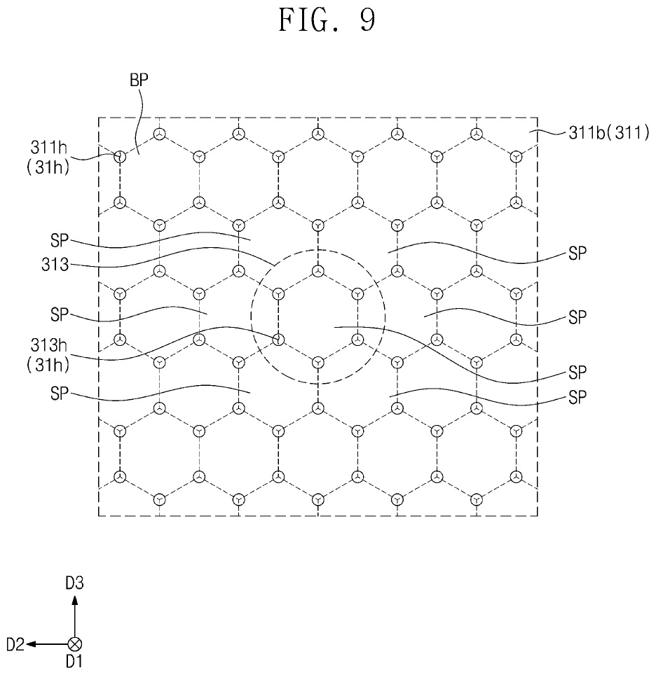

FIG. 8 is a plan view illustrating a portion of a lower shower head part according to an embodiment of the disclosure.

Referring to FIG. 8, the lower plate 311 may include a supporting portion SP and a distribution portion BP. When viewed in a plan view, the supporting portion SP may mean a portion of the lower plate 311, which is not overlapped with the supporting pillar 313. When viewed in a plan view, the distribution portion BP may mean a portion of the lower plate 311, which is at least partially overlapped with the supporting pillar 313. When viewed in a plan view, the supporting portion SP may have substantially the same shape as the distribution portion BP. For example, each of the supporting portion SP and the distribution portion BP may have a hexagonal shape, as shown in FIG. 8. That is, each of the supporting portion SP and the distribution portion BP may have a hexagonal pillar shape.

The gas holes 31h may be provided in the distribution portion BP. For example, each of the gas holes 31h, which are provided in the distribution portion BP, may be the vertical hole 311h. The gas holes 31h, which are provided in the distribution portion BP, may form a first pattern on a top surface of the distribution portion BP. For example, the first pattern may have a hexagonal shape. That is, the gas holes 31h, which are provided in the distribution portion BP, may be arranged in a hexagonal shape. The top surface of the distribution portion BP may be a portion of the top surface 311u of the lower plate 311.

The gas holes 31h may be provided in the supporting portion SP. For example, each of the gas holes 31h, which are provided in the supporting portion SP, may be the vertical hole 311h and the inclined hole 313h. The gas holes 31h, which are provided in the supporting portion SP, may form a second pattern on a top surface of the supporting portion SP. The top surface of the supporting portion SP may be a portion of the top surface 311u of the lower plate 311. In one embodiment, the second pattern may be different from the first pattern. In one embodiment, the second pattern may not have a hexagonal shape, unlike the first pattern. That is, the gas holes 31h, which are provided in the supporting portion SP, may not be arranged in the hexagonal shape. More specifically, as shown in FIG. 8, some of the gas holes 31h, which are provided in the supporting portion SP, may be placed within the hexagonal shape, not at vertices of the hexagonal shape. In one embodiment, the gas holes 31h, which are provided in the supporting portion SP and are placed within the hexagonal shape, may include the inclined hole 313h.

In an embodiment, a plurality of distribution portions BP and a plurality of supporting portions SP may be provided. A number of the distribution portions BP may be greater than a number of the supporting portions SP. So far, the first pattern has been described as having the hexagonal shape, but the disclosure is not limited to this example.

FIG. 9 is a bottom plan view illustrating a portion of a lower shower head part according to an embodiment of the disclosure.

Referring to FIG. 9, the gas holes 31h, which are provided in the distribution portion BP, may form a first pattern on a bottom surface of the distribution portion BP. The bottom surface of the distribution portion BP may be a portion of the bottom surface 311b of the lower plate 311. The gas holes 31h, which are provided in the supporting portion SP, may form the first pattern on a bottom surface of the supporting portion SP. The bottom surface of the supporting portion SP may be a portion of the bottom surface 311b of the lower plate 311.

On the bottom surface 311b of the lower plate 311, the gas holes 31h may be arranged in a specific pattern. That is, the gas holes 31h may be uniformly disposed on the bottom surface 311b of the lower plate 311.

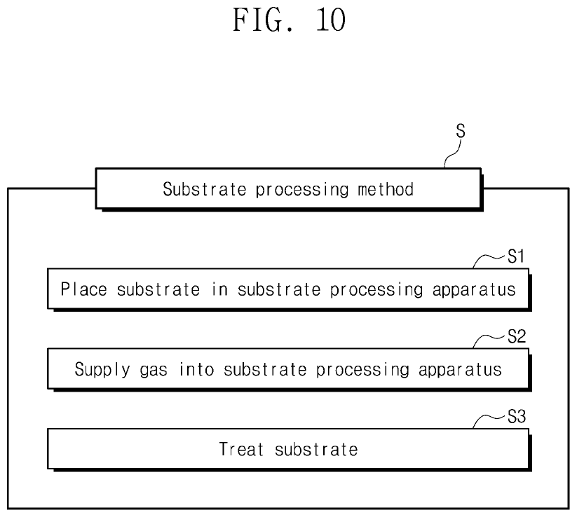

FIG. 10 is a flow chart illustrating a substrate processing method according to an embodiment of the disclosure.

Referring to FIG. 10, a substrate processing method S may be provided. The substrate processing method S may be used to process a substrate using the substrate processing apparatus ‘A’ described with reference to FIGS. 1 to 9. The substrate processing method S may include placing a substrate in a substrate processing apparatus (operation S1), supplying gas into the substrate processing apparatus (operation S2), and treating the substrate (operation S3).

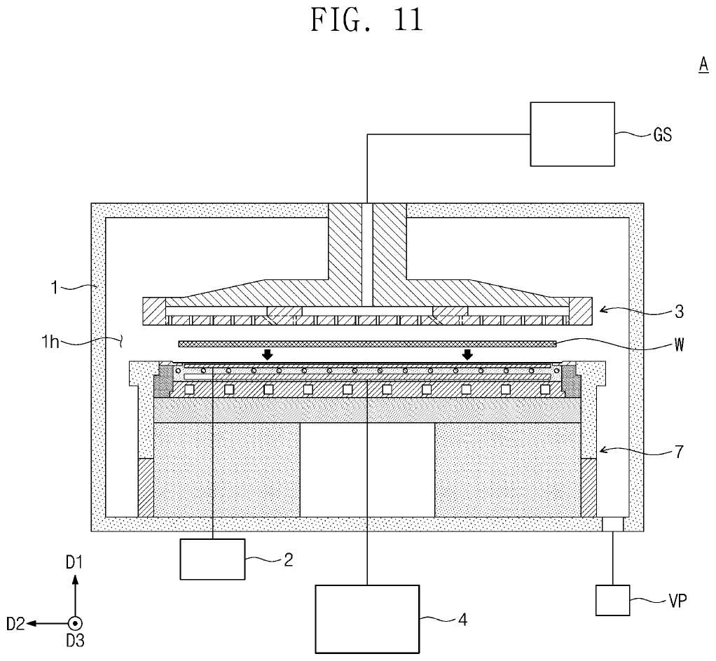

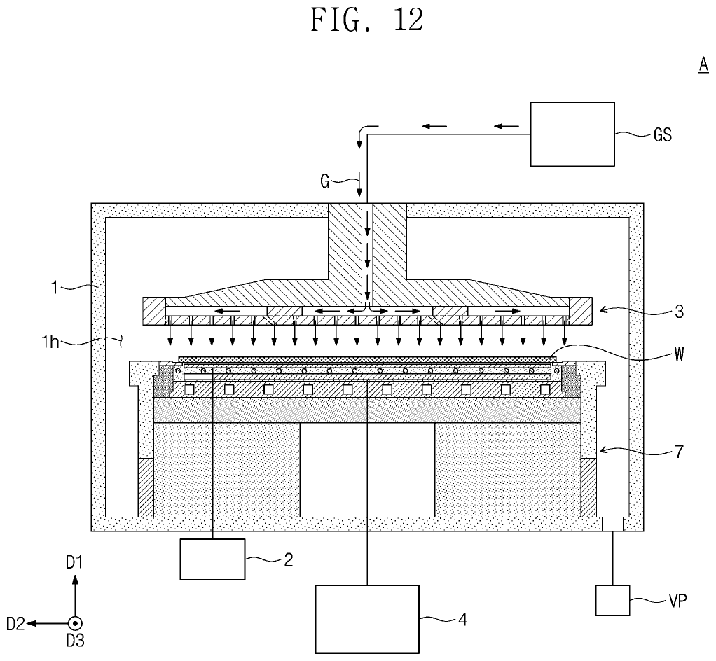

Hereinafter, the substrate processing method S of FIG. 10 will be described in more detail with reference to FIGS. 11 to 14.

FIGS. 11 to 14 are diagrams illustrating a substrate processing method according to the flow chart of FIG. 10.

Referring to FIGS. 11 and 10, the placing of the substrate in the substrate processing apparatus (operation S1) may include placing a substrate W on the stage 7. The substrate W may be disposed on or fastened to the chuck 71.

Referring to FIGS. 12, 13, and 10, the supplying of the gas into the substrate processing apparatus (operation S2) may include supplying the gas G from the gas supplying device GS into the process space 1h. The gas G, which is supplied from the gas supplying device GS, may be distributed onto the substrate W through the shower head 3. More specifically, the gas G may pass through the vertical hole 311h and the inclined hole 313h and then may be distributed onto the substrate W.

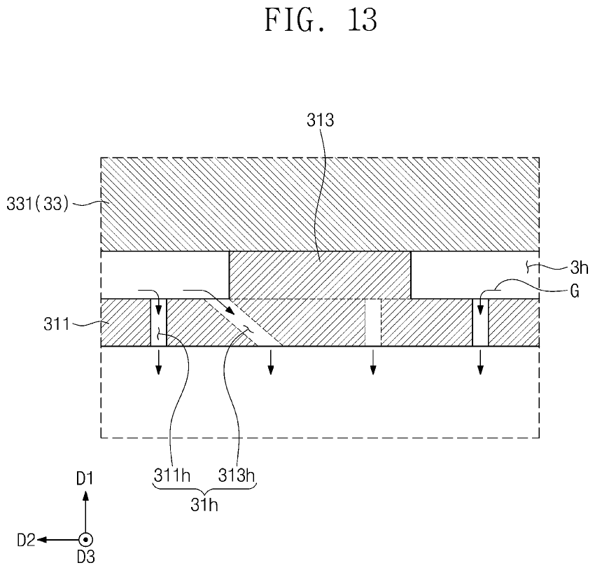

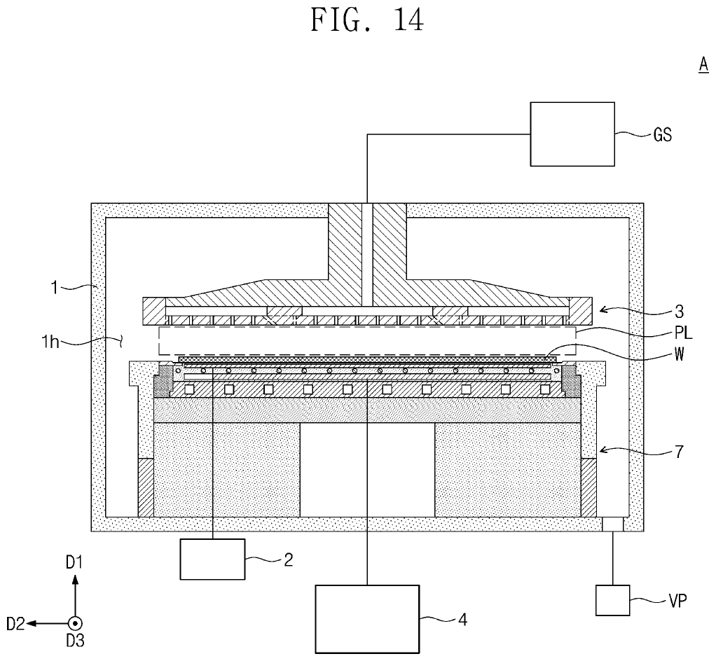

Referring to FIGS. 14 and 10, the treating of the substrate (operation S3) may include treating the substrate W using the gas G (e.g., FIG. 13) and/or plasma PL, which is generated from the gas G. For example, a thin film may be formed on the substrate W. That is, a deposition process may be performed on the substrate W. However, the disclosure is not limited to this example, and an etching process may be performed on the substrate W.

In a shower head according to an embodiment of the disclosure and a substrate processing method including the same, gas holes, which are provided in a lower plate, may be uniformly disposed, even when a supporting pillar is thick. In other words, using the inclined hole, it may be possible to supply gas to a region below the supporting pillar. Thus, the gas may be uniformly sprayed onto the substrate. Accordingly, a deposition process and/or an etching process may be uniformly performed on a substrate.

In a shower head according to an embodiment of the disclosure and a substrate processing method including the same, since a thick supporting pillar can be used, a life span of a shower head may be increased. That is, since the supporting pillar is thick, it may be possible to prevent the supporting pillar from being damaged or broken by a thermal stress. Thus, a high-temperature process involving a rapid temperature change may be effectively performed.

In a shower head according to an embodiment of the disclosure and a substrate processing method including the same, since the inclined hole has a larger diameter, it may be possible to remove a difference in conductance between the vertical hole and the inclined hole, even when the inclined hole has a longer length. Accordingly, an amount of the gas passing through the vertical hole may be controlled to be the same as an amount of the gas passing through the inclined hole. As a result, the gas may be uniformly supplied onto the substrate.

In a shower head according to an embodiment of the disclosure and a substrate processing method including the same, when viewed in a plan view, an inclined hole may be extended from a supporting pillar in an inclined direction. Thus, on a top surface of the lower plate, it may be possible to prevent gas holes from being disposed in a region that is excessively close to the supporting pillar. Accordingly, the gas may be controlled to be uniformly supplied onto the top surface of the lower plate.

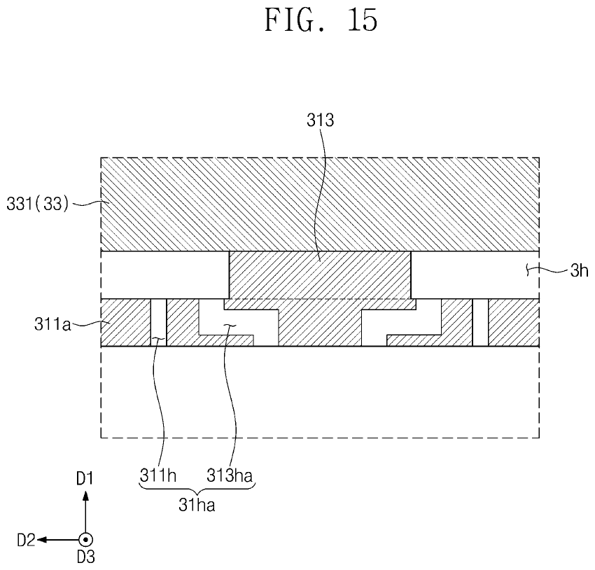

FIG. 15 is a sectional view illustrating a portion of a shower head according to an embodiment of the disclosure.

In the following description, for concise description, an element previously described with reference to FIGS. 1 to 14 may be identified by the same reference number without repeating an overlapping description thereof.

Referring to FIG. 15, a lower plate 311a may be provided to define gas holes 31ha. The gas holes 31ha may include the vertical hole 311h and an inclined hole 313ha. The inclined hole 313ha may include a vertically-extending portion and a horizontally-extending portion. A portion of the inclined hole 313ha, which is connected to a bottom surface of the lower plate 311a, may be vertically extended. Thus, the gas passing through the inclined hole 313ha may be sprayed vertically.

In a shower head according to an embodiment of the disclosure and a substrate processing method including the same, the gas passing through the inclined hole may be sprayed downward from the bottom surface of the lower plate. Thus, it may be possible to uniformly control the gas passing through the vertical hole and the gas passing through the inclined hole.

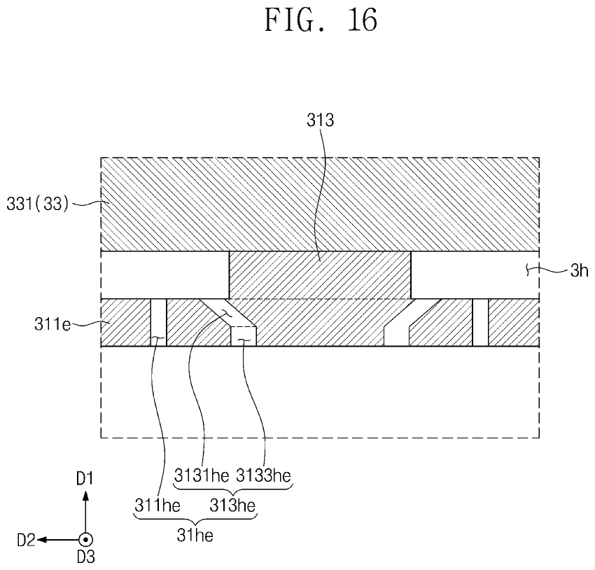

FIG. 16 is a sectional view illustrating a portion of a shower head according to an embodiment of the disclosure.

In the following description, for concise description, an element previously described with reference to FIGS. 1 to 15 may be identified by the same reference number without repeating an overlapping description thereof.

Referring to FIG. 16, a lower plate 311e may be provided to define gas holes 31he. The gas holes 31he may include a vertical hole 311he and an inclined hole 313he. The inclined hole 313he may include an upper hole 3131he and a lower hole 3133he.

The upper hole 3131he may be connected to a top surface of the lower plate 311e. The upper hole 3131he may be inclined at an acute angle to the vertical direction.

The lower hole 3133he may be connected to the upper hole 3131he. The lower hole 3133he may be extended in the vertical direction. The lower hole 3133he may be connected to a bottom surface of the lower plate 311e.

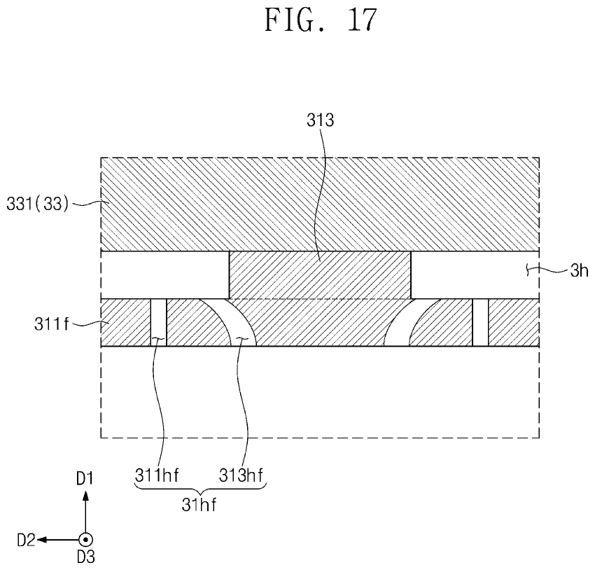

FIG. 17 is a sectional view illustrating a portion of a shower head according to an embodiment of the disclosure.

In the following description, for concise description, an element previously described with reference to FIGS. 1 to 16 may be identified by the same reference number without repeating an overlapping description thereof.

Referring to FIG. 17, a lower plate 311f may be provided to define gas holes 31hf. The gas holes 31hf may include a vertical hole 311hf and an inclined hole 313hf. An extension direction of the inclined hole 313hf may be bent. That is, the inclined hole 313hf may be extended from a top surface of the lower plate 311f toward a bottom surface of the lower plate 311f in a curved shape, as shown in FIG. 17.

In a shower head according to an embodiment of the disclosure and a substrate processing apparatus therewith, it may be possible to use a thick supporting pillar.

In a shower head according to an embodiment of the disclosure and a substrate processing apparatus therewith, it may be possible to uniformly supply a process gas.

In a shower head according to an embodiment of the disclosure and a substrate processing apparatus therewith, it may be possible to increase a life span of the shower head.

While example embodiments of the disclosure have been particularly shown and described, it will be understood by one of ordinary skill in the art that variations in form and detail may be made therein without departing from the spirit and scope of the attached claims.

What is claimed is:

1. A shower head comprising:
a lower shower head part,
wherein the lower shower head part comprises a lower plate,
wherein the lower plate comprises a plurality of gas holes,
wherein the plurality of gas holes comprises:
a vertical hole vertically penetrating the lower plate in a first direction; and
an inclined hole penetrating the lower plate in a second direction, which is inclined at an acute angle with respect to the first direction of the vertical hole, and
wherein the vertical hole has a first diameter and the inclined hole has a second diameter which is different than the first diameter.

2. The shower head of claim 1, wherein the second diameter is larger than the first diameter.

3. The shower head of claim 2, wherein the vertical hole has a first length and the inclined hole has a second length which is larger than the first length, and
wherein a ratio of a fourth power of the first diameter to the first length is equal to a ratio of a fourth power of the second diameter to the second length.

4. The shower head of claim 1, further comprising an upper shower head part on the lower shower head part,
wherein the upper shower head part comprises an upper plate spaced apart from the lower plate in an upward direction, and
wherein the lower shower head part further comprises a supporting pillar extending upward from the lower plate and coupled to the upper plate.

5. The shower head of claim 4, wherein a lower end of the inclined hole overlaps the supporting pillar, when viewed in a plan view.

6. The shower head of claim 5, wherein the second direction of the inclined hole is inclined at an acute angle to a straight line connecting a center of the lower end of the inclined hole to a center of the supporting pillar, when viewed in a plan view.

7. The shower head of claim 4, wherein the lower shower head part further comprises an edge coupling ring extending upward from an edge portion of the lower plate and coupled to the upper shower head part, and
wherein the supporting pillar is placed in the edge coupling ring.

8. The shower head of claim 4, wherein the supporting pillar has a diameter in a range of 7 mm to 13 mm.

9. The shower head of claim 1, wherein the lower plate has a thickness that is constant, and
a bottom surface of the lower plate is substantially flat.

10. The shower head of claim 1, wherein the lower plate comprises aluminum.

11. A shower head comprising:
a lower shower head part; and
an upper shower head part on the lower shower head part,
wherein the lower shower head part comprises:
a lower plate that comprises a plurality of gas holes; and
at least one supporting pillar extended from a top surface of the lower plate and coupled to the upper shower head part,
wherein the plurality of gas holes comprises:
a vertical hole penetrating the lower plate in a first direction; and
an inclined hole penetrating the lower plate and spaced apart from the vertical hole,
wherein an upper end of the inclined hole, which meets the top surface of the lower plate, is beside the at least one supporting pillar, and
wherein a lower end of the inclined hole, which meets a bottom surface of the lower plate, is below the at least one supporting pillar.

12. The shower head of claim 11, wherein a first straight line connecting a center of the upper end of the inclined hole to a center of the lower end of the inclined hole is inclined at an acute angle to a second straight line, and
wherein the second straight line connects the center of the lower end of the inclined hole to a center of the at least one supporting pillar, when viewed in a plan view.

13. The shower head of claim 11, wherein the vertical hole has a first diameter and the inclined hole has a second diameter that is larger than the first diameter.

14. The shower head of claim 11, wherein the upper shower head part comprises:
an upper plate extended from the lower plate in an upward direction; and
a supporting member extended from the upper plate in an upward direction, and
wherein the supporting member defines a gas supplying pathway, which is connected to a distribution space between the upper plate and the lower plate.

15. The shower head of claim 11, wherein the at least one supporting pillar comprises a plurality of supporting pillars that are spaced apart from each other in a horizontal direction.

16. A substrate processing apparatus comprising:
a shower head,
wherein the shower head comprises a lower shower head part,
wherein the lower shower head part comprises:
a lower plate that comprises a plurality of gas holes; and
a supporting pillar extended upward from a top surface of the lower plate,
wherein the lower plate comprises:
at least one supporting portion which at least partially overlaps the supporting pillar, in a plan view; and
a distribution portion which does not overlap the supporting pillar and is beside the at least one supporting portion, in a plan view,
wherein the plurality of gas holes comprises:
a first gas holes in the distribution portion and arranged in a first pattern on a top surface of the distribution portion,
a second gas holes in the distribution portion and arranged in the first pattern on a bottom surface of the distribution portion,
a third gas holes in the at least one supporting portion and arranged in a second pattern on a top surface of the at least one supporting portion, the second pattern being different from the first pattern, and
a fourth gas holes in the at least one supporting portion and arranged in the first pattern on a bottom surface of the at least one supporting portion.

17. The substrate processing apparatus of claim 16, wherein the distribution portion comprises a plurality of distribution portions,
wherein the at least one supporting portion comprises a plurality of supporting portions, and
wherein a number of the distribution portions is greater than a number of the plurality of supporting portions.

18. The substrate processing apparatus of claim 16, wherein a diameter of each of the third gas holes and the fourth gas holes is larger than a diameter of each of the first gas holes and the second gas holes.

19. The substrate processing apparatus of claim 16, wherein at least one of the first gas holes and the second gas holes comprises:
an upper hole connected to the top surface of the lower plate and extending in a direction inclined at an acute angle to a vertical direction; and
a lower hole extending from the upper hole in the vertical direction and connected to a bottom surface of the lower plate.

20. The substrate processing apparatus of claim 16, further comprising:
a process chamber providing a process space; and
a stage in the process chamber,
wherein the shower head is spaced apart from the stage in an upward direction.
